(19) United States
(12) Patent Application Publication
(10) Pub. No.: US 2026/0206146 A1
(43) Pub. Date: Jul. 16, 2026

(54) HOT AIR LIQUID CONDUCTIVE COOLING (HALCC) DEVICE

(71) Applicant: Flex Ltd., Singapore (SG)

(72) Inventors: Ricky J Payne, Plano, TX (US); David Michael Mendez, Austin, TX (US); Po-Jen Huang, San Jose, CA (US); Douglas M Watson, Austin, TX (US); Peng Fei Liao, New Taipei City (TW); Chin Kee Chen, New Taipei City (TW); Kuo Ming Huang, Taipei City (TW); Lan Chih HSIUNG, New Taipei City (TW); Fu-Lin Peng, New Taipei City (TW); Li Tzu CHENG, New Taipei City (TW)

(73) Assignee: Flex Ltd., Singapore (SG)

(21) Appl. No.: 19/024,926

(22) Filed: Jan. 16, 2025

(51) Int. Cl. H05K 3/34

(52) U.S. Cl. CPC H05K 3/3494; H05K 2203/1121

(57) ABSTRACT

An apparatus includes a tank containing a liquid medium at a predetermined temperature and a top cover. A second side of the top cover is in contact with a top surface of the tank. The apparatus further includes a printed circuit board assembly (PCBA) having a first side and a second side and attached to the top cover, a plurality of circuit components, and a nozzle. At least one of the plurality of circuit components is provided on the first side of the PCBA and at least another of the plurality of circuit components is provided on the second side of the PCBA, below the second side of the top cover and submerged in the liquid medium and the nozzle provides heat from a heat source to the at least one of the plurality of circuit components provided on the first side of the PCBA for rework or removal.

### FIELD

The present disclosure is related generally to methods, systems and devices for rework and assembly of components (e.g., electrical components and electronic components) on a printed circuit board assembly (PCBA), and more specifically to methods, systems, and devices for rework and assembly of components provided on a double-sided PCBA.

### BACKGROUND

It is often necessary to rework PCBA-mounted components, such as resistors, capacitors, inductors, transformers, integrated circuit (IC) packages such as ceramic ball grid array packages (CBGA), ceramic column grid array packages (CCGA), plastic ball grid array packages (PBGA), or other surface mount technology (SMT) components and quad flat packs (QFP), connectors, headers, radio frequency (RF), light emitting diode (LED)s, switches, board interface systems, battery sockets, etc. if the component or solder joints with the PCBA are faulty. A common problem with removing and replacing such components is the difficulty in heating the solder securing the component to a temperature sufficiently high to melt the solder without damaging the PCBA, the component or other adjacent components.

Conventional rework and reflow stations use a variety of methods for heating the solder, including hot air, infrared heating, hot plates, lasers, or vapor phase. Currently, hot air or hot nitrogen gas are currently being used in conventional rework stations. Various problems are experienced with these forms of heating, including, for example, overheating or poor uniformity of heating due to shadowing, deflection or reflection, which may cause or result in cold solder joints, overheated solder joints, improperly resoldered joints, and stress damage to the PCBA, the targeted component, and/or the surrounding components.

When handling a double-sided PCBA (e.g., when components are provided on a topside and a bottom side of the PCBA), for example, not only does the solder attaching the targeted component(s) provided on the topside of the PCBA goes liquidous during a rework process, a corresponding area on the bottom side of the PCBA is compromised (e.g., the solder attaching the components on the bottom side of the PCBA may also go liquidous).

Accordingly, there is a need for methods, systems and devices for heating a targeted component to a temperature sufficient to reflow the solder joint interconnecting the targeted component on the PCBA without affecting other nontargeted components on the PCBA provided on the same side as the PCBA or on the opposite side of the PCBA.

### SUMMARY

Embodiments of the present disclosure provide an apparatus, a method and a reflow method for reworking or removing circuit components provided on both sides of a printed circuit board assembly (PCBA). According to one embodiment of the present disclosure, an apparatus for reworking or removing circuit components provided on both sides of a PCBA includes a tank containing a liquid medium at a predetermined temperature and a top cover having a first side and a second side opposite to the first side. The second side of the top cover is in contact with a top surface of the tank. The apparatus also includes a PCBA having a first side and a second side opposite the first side and attached to the top cover and a plurality of circuit components. At least one of the plurality of circuit components is provided on the first side of the PCBA and at least another of the plurality of circuit components is provided on the second side of the PCBA, below the second side of the top cover and submerged in the liquid medium. The apparatus further includes a nozzle connectable with a heat source and providing heat from the heat source to the at least one of the plurality of circuit components provided on the first side of the PCBA for rework or removal.

Aspects of the above apparatus include wherein the liquid medium is maintained at the predetermined temperature during providing heat to the at least one of the plurality of circuit components provided on the first side of the PCBA for rework or removal.

Aspects of the above apparatus include wherein the heat to the at least one of the plurality of circuit components provided on the first side of the PCBA for rework or removal is at a temperature higher than a melting temperature of solder bonded to the at least one of the plurality of circuit components provided on the first side of the PCBA such that the solder is melted.

Aspects of the above apparatus include wherein the liquid medium covers 0.75 millimeters (mm) or less of the second side of the PCBA.

Aspects of the above apparatus include wherein the liquid medium includes at least one of Gaulden HT, a class of organofluorine compounds that include perfluoropolyether (PFPE) fluorinated fluid.

Aspects of the above apparatus include wherein the tank includes a temperature sensor used to monitor the temperature of the liquid medium.

Aspects of the above apparatus include wherein the tank includes a two-layer structure of an inner layer and an outer layer surrounding an inner tank region of the tank and wherein the liquid medium is provided within the inner tank region.

Aspects of the above apparatus include wherein the inner layer is a circulatory layer that includes silicon, and the outer layer is an insulating layer that includes rock wool.

Aspects of the above apparatus include wherein the predetermined temperature is in a range of 150° C. to 290° C.

Aspects of the above apparatus include wherein the solder includes tin (Sn), lead (Pb), silver (Ag), copper (Cu), zinc (Zn), bismuth (Bi), antimony (Sb), gold (Au) and/or indium (In).

Aspects of the above apparatus include wherein the top cover is interchangeable based on a number of the plurality of circuit components provided on the first side of the PCBA.

Aspects of the above apparatus include wherein the melting temperature of the solder ranges from 118° C. to 280° C.

According to one embodiment of the present disclosure, a method for reworking or removing circuit components provided on both sides of a printed circuit board assembly (PCBA) includes providing a printed circuit board assembly (PCBA) with circuit components provided on a first side and a second side, opposite the first side of the PCBA, immersing the circuit components provided on the second side of the PCBA into a tank containing a liquid medium at a predetermined temperature and providing a nozzle connectable with a heat source over at least one of the circuit components provided on the first side of the PCBA for rework or removal while maintaining the predetermined temperature of the liquid medium.

Aspects of the above method further include heating the at least one of the circuit components provided on the first side of the PCBA to a temperature higher than a melting temperature of solder bonded to the at least one of the circuit components provided on the first side of the PCBA such that the solder is melted.

Aspects of the above method include wherein the liquid medium includes at least one of Gaulden HT, a class of organofluorine compounds that include perfluoropolyether (PFPE) fluorinated fluid.

Aspects of the above method further include providing the tank to include a two-layer structure of an inner layer and an outer layer surrounding an inner tank region of the tank and providing the liquid medium within the inner tank region.

Aspects of the above method further include providing the inner layer with silicon and providing the outer layer with rock wool.

Aspects of the above method further include providing the melting temperature of the solder in a range of 118° C. to 280° C.

Aspects of the above method further include interchanging the top cover based on a number of the circuit components provided on the first side of the PCBA.

According to one embodiment of the present disclosure, a reflow method includes loading a reflow profile of a printed circuit board assembly (PCBA) into a reflow system, installing the PCBA provided within a rework device into a reflow chamber machine of the reflow system, providing a nozzle connectable with a heat source over the at least one of the plurality of circuit components provided on the first side of the PCBA for rework or removal while maintaining the predetermined temperature of the liquid medium, performing rework on the at least one of the plurality of circuit components provided on the first side of the PCBA and updating the reflow profile based on a result of the rework performed on the at least one of the plurality of circuit components provided on the first side of the PCBA.

The reflow device includes a tank containing a liquid medium at a predetermined temperature, a top cover having a first side and a second side opposite to the first side and a plurality of circuit components. The second side of the top cover is in contact with a top surface of the tank, the PCBA has a first side and a second side opposite the first side and attached to the top cover and at least one of the plurality of circuit components is provided on the first side of the PCBA and at least another of the plurality of circuit components is provided on the second side of the PCBA, below the second side of the top cover and submerged in the liquid medium.

These and other needs are addressed by the various embodiments and configurations of the present disclosure. The present disclosure can provide a number of advantages depending on the particular configuration. These and other advantages will be apparent from the disclosure contained herein.

### BRIEF DESCRIPTION OF THE DRAWINGS

FIG. 1 is a diagram illustrating a cross-sectional view of an example conventional hot air rework station;

FIG. 2 is a diagram illustrating a cross-sectional view of an example hot air liquid conductive cooling rework device according to an embodiment of the present disclosure;

FIG. 3 is a diagram illustrating a cross-sectional view of an alternative example hot air liquid conductive cooling rework device according to an embodiment of the present disclosure;

FIG. 4 is a diagram illustrating a cross-sectional view of a liquid conductive cooling rework device according to an embodiment of the present disclosure;

FIG. 5 is a diagram illustrating an example hot air liquid conductive cooling rework system according to an embodiment of the present disclosure;

FIG. 6a is a diagram illustrating an isometric view of a liquid conductive cooling rework device with the top fixture separated from the tank according to an embodiment of the present disclosure;

FIG. 6b is a diagram illustrating an isometric view of a liquid conductive cooling rework device with the top fixture connected to the tank according to an embodiment of the present disclosure;

FIG. 7 is a block diagram illustrating a computing system used with the hot air liquid conductive cooling rework system according to an embodiment of the present disclosure;

FIG. 8 is a block diagram of an example reflow module for the hot air liquid conductive cooling rework system according to an embodiment of the present disclosure; and

FIG. 9 is a flowchart illustrating an example method for rework and assembly of components provided on a double-sided PCBA used with the hot air liquid conductive cooling rework system according to an embodiment of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

Embodiments of the present disclosure are directed to methods, devices and systems for rework and assembly of components provided on a double-sided PCBA.

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only and is not intended to limit the scope or applicability of the disclosure. Furthermore, to avoid unnecessarily obscuring the present disclosure, the preceding description omits a number of known structures and devices. This omission is not to be construed as a limitation of the scope of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configurations, and aspects.

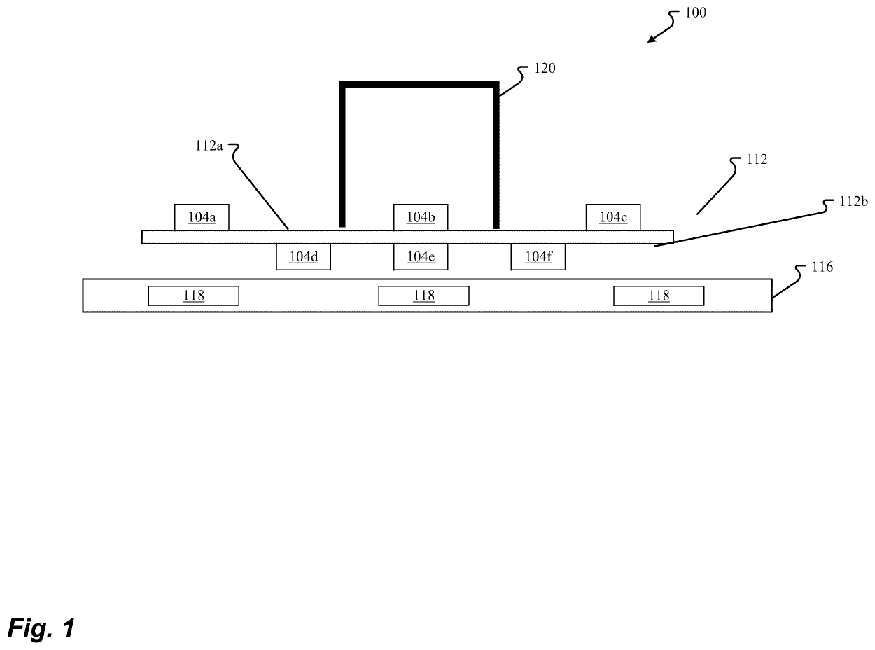

FIG. 1 is a diagram illustrating a cross-sectional view of an example conventional hot air rework station 100. The conventional hot air rework station 100 generally includes a base 116, a printed circuit board assembly (PCBA) 112 including components 104a-104c (e.g., electrical components and electronic components) provided on a first or a topside 112a of the PCBA 112, components 104d-104f (e.g., electrical components and electronic components) provided on a second or bottom side 112b of the PCBA 112, and a nozzle 120. The PCBA 112 is fixtured above the base 116. The base 116 may be a heater plenum and may include heating elements 118 provided under, within, and/or above the base 116 used to control the temperature of the bottom side 112b of the PCBA 112 during the hot air rework process using convention heating for example. For example, the heating elements 118 may be infrared (IR) preheaters used with the hot air rework process. Heat is irradiated or blown from the heating elements 118 at 150° C., for example, to heat the bottom side 112b of the PCBA 112 before and/or during the rework process. The heat from the heating elements 118 also heats the topside 112a of the PCBA 112 which gets the entire PCBA 112 warm.

As illustrated in FIG. 1, the nozzle 120 is provided over a targeted component 104b. The nozzle 120 includes a heating element (not shown) to heat a gas to a temperature adequate to melt the solder used to connect the component 104b to the PCBA 112. As used herein “gas” means any fluid substance capable of conveying heat or cold and includes air as well as inert gases such as nitrogen.

The removal of any of the components 104a-104c from the topside 112a of the PCBA 112 requires high heat. For example, the temperature to remove components (e.g., making the solder turn liquidus) is above 221° C. and more particularly, in the 235° C. range. This high heat affects neighboring components (e.g., component 104a and component 104c) on the topside 112a of the PCBA 112 as well as components 104d-104f on the bottom side 112b of the PCBA 112.

Although the conventional hot air rework station 100 including the nozzle 120 providing hot air at a temperature to remove a targeted component and the heating elements 118 providing irradiated heat to a bottom side 112b of the PCBA 112 at a temperature to prevent solder from flowing during the rework process, the conventional hot air rework station 100 suffers from not being able to maintain a temperature sufficient to prevent solder from flowing (e.g., making the solder turn liquidus) on the bottom side 112b of the PCBA 112 during the rework process.

According to one embodiment of the present disclosure, a double-sided PCBA is provided. The bottom side of the double-sided PCBA (e.g., the side that is not being reworked) is submerged into a tank with a heated dielectric solution provided therein. The heated dielectric solution is provided such that the components on the bottom side of the double-sided PCBA (e.g., nontargeted components) are submerged, but the bottom side of the double-sided PCBA is in intimate contact (e.g., slightly above or slightly in contact) with the dielectric solution. According to at least one embodiment of the present disclosure, the dielectric solution level is in the range of 0.5 millimeters (mm) to 1.0 mm higher than the bottom side of the double-sided PCBA with a preferred level being 0.75 mm higher than the bottom side of the double-sided PCBA.

According to the embodiment of the present disclosure, the dielectric solution has an operating temperature in a range between 125° C. to 350° C. and more specifically in a range between 150° C. to 290° C. The dielectric solution ensures that the bottom side of the PCBA remains at a selected controlled temperature sufficient to prevent solder from flowing (e.g., making the solder liquidus). Thus, the heat conduction on the bottom side of the PCBA is managed by the thermally controlled dielectric solution and the nontargeted components are prevented from being damaged due to increased heat when a targeted component needs to be reworked. As compared with the conventional hot air rework station, where hot air or irradiated heat is applied to the entire bottom side of the PCBA during the rework process to avoid thermal shock at the isolated rework site (e.g., the targeted component) the thermally controlled dielectric solution of the present embodiment takes the place of the hot air or irradiated heat from the heating elements with a much higher specific heat to keep the bottom side of the PCBA at or below 200° C. (e.g., that is below the melting temperature of solder or any other metal or metal alloy materials).

According to an alternative embodiment of the present disclosure, a double-sided PCBA is provided where some of the components provided on the frontside of the PCBA are spaced close to each other (e.g., neighboring components). For example, some of the neighboring components provided on the topside of the PCBA are spaced within an inch or less from each other. To ensure that the nontargeted neighboring components are not affected by the hot air reflow process of a targeted component, the dielectric solution is applied to the neighboring nontargeted component(s) that are spaced one inch or less from the targeted component(s). For example, a wall, a barrier, a moat, a trench, a dike, etc., may be provided to surround the nontargeted component(s) such that the targeted component(s) are separated from the nontargeted neighboring component(s). The dielectric solution is provided within the wall, the barrier, the moat, the trench, the dike, etc. of the neighboring nontargeted component(s). The dielectric solution is at room temperature or cooler. For example, the temperature of the dielectric solution is in the range of 15° C. to 20° C. or cooler.

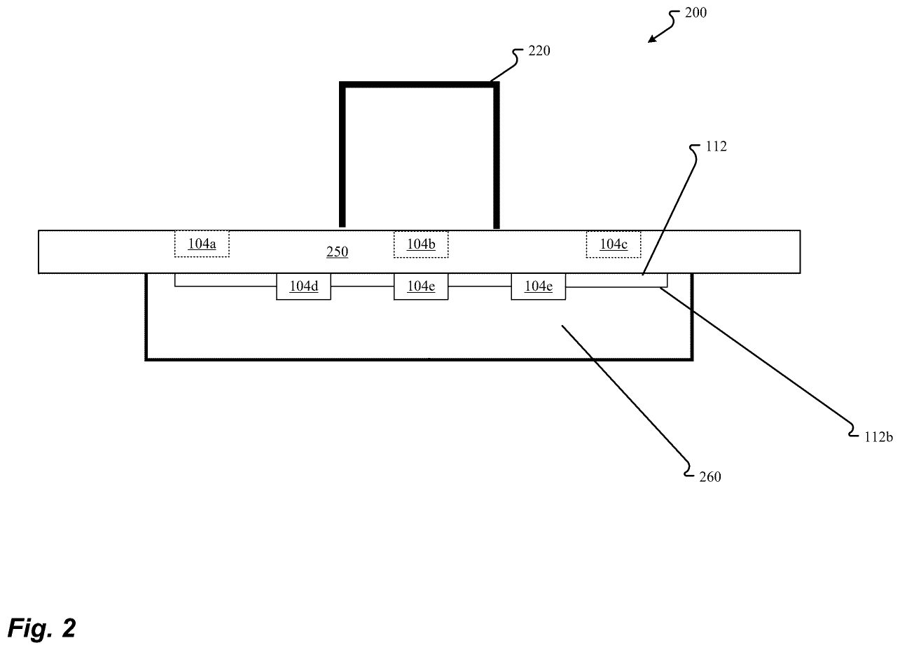

FIG. 2 is a diagram illustrating a cross-sectional view of an example hot air liquid conductive cooling rework device 200 according to an embodiment of the present disclosure. The hot air liquid conductive cooling rework device 200 generally includes a tank 260, a PCBA 112 including components 104a-104c (e.g., electrical components and electronic components) on a first or a topside of the PCBA 112 and components 104d-104f on a second or bottom side 112b of the PCBA 112, a top fixture 250 and a nozzle 220. According to an embodiment of the present disclosure, the components may include resistors, capacitors, inductors, transformers, integrated circuits (IC) packages such as ceramic ball grid array packages (CBGA), ceramic column grid array packages (CCGA), plastic ball grid array packages (PBGA), or other surface mount technology (SMT) components and quad flat packs (QFP), connectors, headers, radio frequency (RF), light emitting diode (LED)s, switches, board interface systems, battery sockets, etc. The nozzle 220 is similar to the nozzle 120 illustrated in FIG. 1, therefore a detailed description will be omitted.

The top fixture 250 supports the PCBA 112 and the components 104a-104c and 104d-104f and is secured to the top of the tank 260 during a hot air reflow process. The components 104a-104c and 104d-104f are secured to the PCBA 112 by solder, for example. According to an embodiment of the present disclosure, the melting point of solder ranges from 118° C. to 280° C. More particularly, the melting point of solder is 221° C. for SAC 305 and 183°C. for Tin/Lead 63n37Pb. Examples of solders that can be melted and/or removed from PCBAs include those solders comprising tin (Sn), lead (Pb), silver (Ag), copper (Cu), zinc (Zn), bismuth (Bi), antimony (Sb), cadmium (Cd), gallium (Ga), germanium (Ge), gold (Au), and/or indium (In). PCSs including lead or lead-free solder can be treated. In certain embodiments of the present disclosure, the solder contains Sn, optionally in combination with one or more of Pb, Ag, Cu, Zn, Bi, Sb, Cd, Ga, Ge, Au, and/or In. In some embodiments of the present disclosure, the solder contains Au and/or Sn). The size range of the components 104a-104c and 104d-104f is as small as 0.5 mm to 120 mm for BGAs, BTCs and other area array components as well as connectors. More particularly, the size range of the components 104a-104c and 104d-104f is 20 mm×20 mm up to 75 mm×75 mm.

According to an embodiment of the present disclosure, the top fixture 250 functions as a templet for the various PCBAs based on the number and the size of components provided on the topside of the PCBA. For example, if five (5) components are provided on a PCBA, then a top fixture having (5) cutouts or windows are provided to accommodate the (5) components. The top fixture 250 may be formed from any suitable material(s) such as, for example,, a metal or a metal alloy, a fiber glass reinforced composite material with high strength, anti-static, high temperature resistance material (e.g., Durostone®), a high strength, chemical corrosion resistance, anti-static, high temperature resistance, low thermal conductivity, flame retardant material (e.g., Stononlead®), etc., and may be formed from a single material or may include different portions formed from different materials and/or via different manufacturing processes.

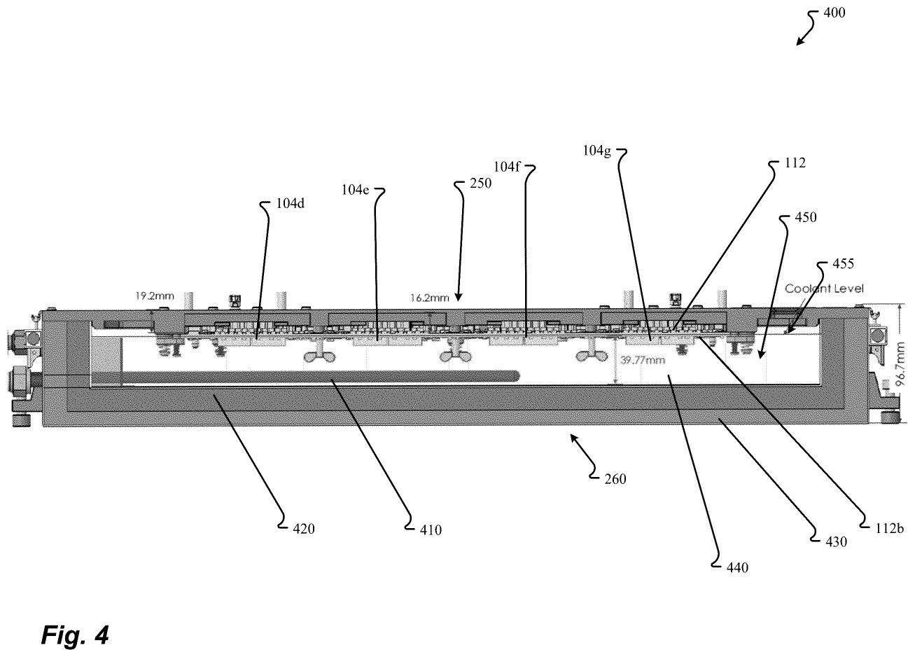

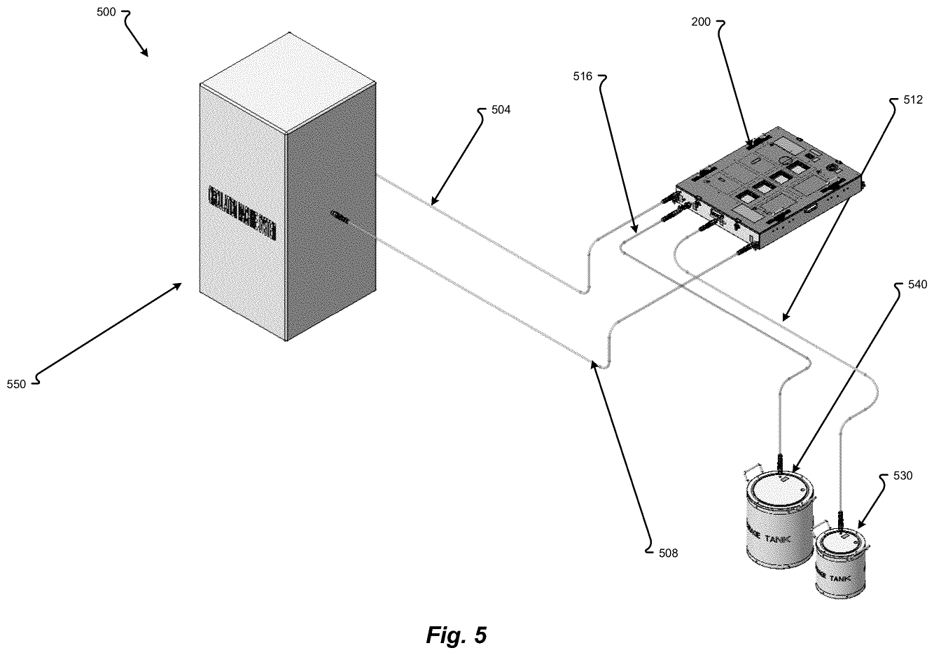

As discussed in greater detail below with FIGS. 4 and 5, the tank 260 has a two-layer structure (an inner layer and an outer layer) surrounding an inner tank region. The inner layer is a circulatory layer, and the outer layer is an insulating layer. The inner tank region is provided with a dielectric solution (e.g., a coolant). The inner layer is provided with a thermally conductive media used to maintain a steady state temperature of the components 104d-104f by controlling the temperature of the dielectric solution and circulated by a circulating machine as discussed in FIG. 5. Examples of the dielectric solution include, but are not limited to, Gaulden HT, for example, operating in a range of 150° C. to 200° C., a class of organofluorine compounds that include perfluoropolyether (PFPE) fluorinated fluid, hot oil, etc. Examples of the thermally conductive media include, but are not limited to silicone oil, etc., a transparent, high-performance, hydrocarbon-based heat transfer fluid that has very low toxicity and with a working temperature +40° C. to +300° C. (e.g., white mineral oil or Thermal H300®), a dark brown, transparent methyl silicon fluid with thermal stability used at 250° C. (e.g., CGF-56®-heat transfer fluid having the same properties as polydimethylsiloxane), a methyl phenyl silicon fluid having flash point greater than 300° C. or any thermally conductive fluid that can operate in the temperature range of 150° C. to 290° C.

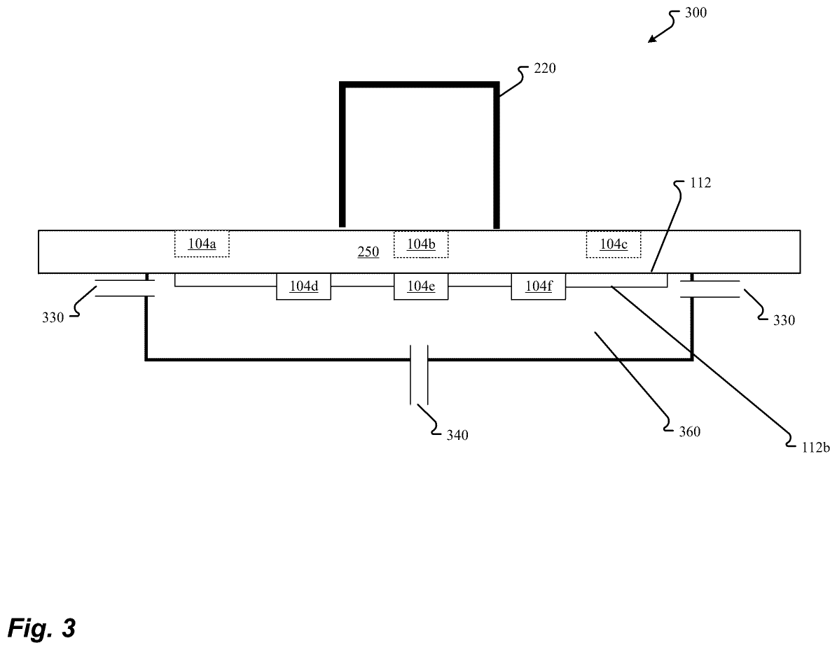

FIG. 3 is a diagram illustrating a cross-sectional view of an alternative example hot air liquid conductive cooling rework device 300 according to an embodiment of the present disclosure. The alternative hot air liquid conductive cooling rework device 300 generally includes a tank 360 including inlet ports 340 (only one inlet port 340 is shown in the drawing) outlet ports 330, a PCBA 112 including components 104a-104c (e.g., electrical components and electronic components) on a first or a topside of the PCBA 112 and components 104d-104f on a second or bottom side 112b of the PCBA 112, a top fixture 250 and a nozzle 220.

The top fixture 250 supports the PCBA 112 and the components 104a-104c and 104d-104f and is secured to the top of the tank 360 during a hot air reflow process. Since the tank 360 does not have a two-layer structure with an inner layer and an outer layer surrounding an inner tank region, the inlet ports 340 and the outlet ports 330 are provided to maintain the temperature of the dielectric solution. Instead of a thermally conductive media being circulated within the inner layer of the tank, the dielectric solution circulates within the tank 360 using a circulating machine as discussed in FIG. 5 such that the dielectric solution flows at 10-50 ml/min at a constant temperature.

According to a further alternative embodiment of the present disclosure, a tank is provided that does not have a two-layer structure within an inner layer and an outer layer surrounding an inner tank region or inlet and outlet ports. According to this further alternative embodiment of the present disclose, the dielectric solution is provided in the tank, and the temperature of the dielectric solution is maintained during a hot air reflow process by a heating element or similar device.

FIG. 4 is a diagram illustrating a cross-sectional view of a liquid conductive cooling rework device 400 according to an embodiment of the present disclosure. As illustrated in FIG. 4, the liquid conductive cooling rework device 400 includes the tank 260, the top fixture 250 and the PCBA 112 having components 104d-104g attached to the bottom side 112b of the PCBA 112. The tank 260 has a substantially rectangular configuration and includes an inner layer 420, an outer layer 430 and an inner tank 440. The inner layer 420 functions as a circulating layer for a conductive fluid. The outer layer 430 functions as a heat preservation/insulation layer and is made of rock wool. The inner tank 440 is made of stainless steel, for example, and includes a coolant 450 and a temperature sensor 410 for measuring the temperature of the coolant 450. The circulating layer (e.g., the inner layer 420) and the inner tank 440 provide a sealed system to increase circulation efficiency. The circulating fluid can be silicone oil, for example. When silicone oil is used as the circulating fluid, the silicone oil volume flow rate is 10 liters/minute, and an inlet temperature of the silicon oil is 165° C. The coolant 450 (e.g., dielectric solution) tank 260 is thermally controlled (e.g., heated/cooled) by circulating the conductive fluid to maintain or control the coolant 450 at a temperature between 150° C. to 200° C. through the inner layer 420. The tank 260 further includes exhaust, re-fill and overflow ports to clean, refill and prevent the coolant 450 from overflowing out from the tank 260. The coolant 450 is filled to the coolant level 455. As illustrated in FIG. 4, the coolant 450 is provided such that the components 204a-204d provided on the bottom side of the PCBA 112 are submerged, but the bottom side of the PCBA 112 is in intimate contact (e.g., slightly above or slightly in contact) with the coolant 450. According to at least one embodiment of the present disclosure, the coolant level 451 is 0.75 millimeters (mm) higher than the bottom side of the PCBA 112.

According to a further embodiment of the present disclosure, the tank 260 may, for example, have a width in the range of 500 mm to 600 mm and more specifically may have a width in the range of 525 mm to 675 mm and more specifically 552.0 mm. The tank 200 may, for example, also have depth in the range of 650 mm to 750 mm and more specifically may have a depth in the range of 675 mm to 725 mm and more specifically 700.2 mm. The tank 200 may, for example, further have a height in the range of 90 mm to 100 mm and more specifically may have a height in the range of 94 mm to 96 mm and more specifically 94.7 mm, have dimensions of 552.2 mm for the width, 700.2 mm for the depth and 94.7 mm for the height.

FIG. 5 is a diagram illustrating an example hot air liquid conductive cooling rework system 500 according to an embodiment of the present disclosure. The hot air liquid conductive cooling rework system 500 illustrated in FIG. 5 generally includes the hot air liquid conductive cooling rework device 200 illustrated in FIG. 2 (or a hot air liquid conductive cooling rework device 300 illustrated in FIG. 3), an overflow storage tank 530, an exhaust storage tank 540 and a circulating machine 550. The overflow storage tank 530 is connected to the hot air liquid conductive cooling rework device 200 by an outlet pipe 512 and exhaust storage tank 540 is connected to the hot air liquid conductive cooling rework device 200 by an inlet pipe 516. Moreover, the circulating machine 550 connects to the hot air liquid conductive cooling rework device 200 by a tank inlet pipe 508 and a tank outlet pipe 504.

The circulating machine 550 includes a pump that operates with a flow rate of 35-45 L/min at 0.5 Kg. The circulating machine 550 further includes a heater (e.g., a seamless electric heating pipe operating at 12 KW/silicon control rectifier (SCR), an oil tank (e.g., a sealed stainless steel oil tank with a total capacity of 30 liters, a temperature controller having a maximum temperature of 300° C., safety protection features (e.g., indicator light(s), alarm device, automatic exhaust device low liquid level cut-off protection, pump overload abnormality protection, etc.), circulating pipes (e.g., two stainless steel mesh pipes including thermal insulation sleeves), and a conductive fluid (e.g., silicon oil, etc.). The overflow storage tank 530 and the exhaust storage tank 540 are stainless steel insulation storage tanks for example. The circulating machine 550, the overflow storage tank 530 and the exhaust storage tank 540 are used to circulate the thermally conductive fluid as discussed above in FIG. 2 or circulate the dielectric solution (e.g., the coolant) discussed above in FIG. 3.

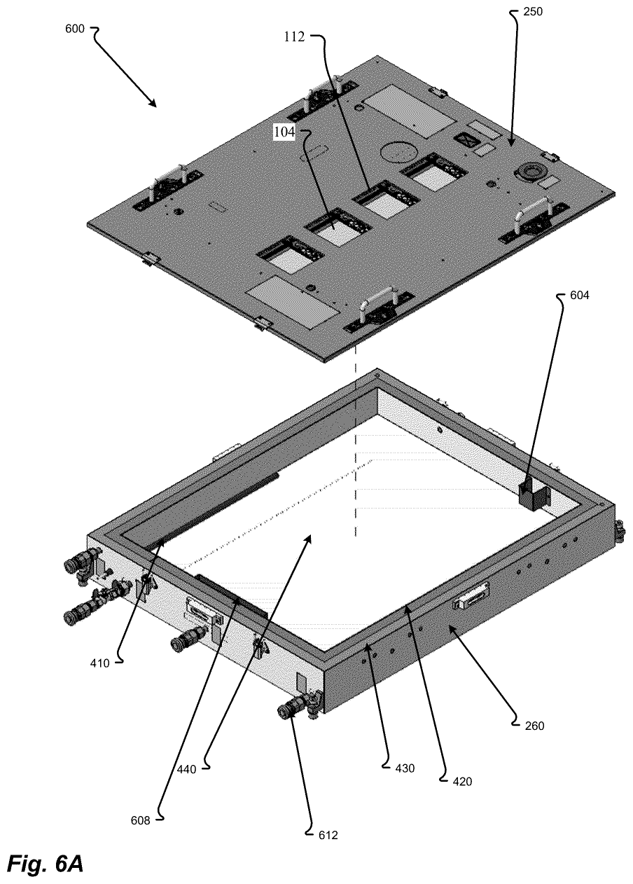

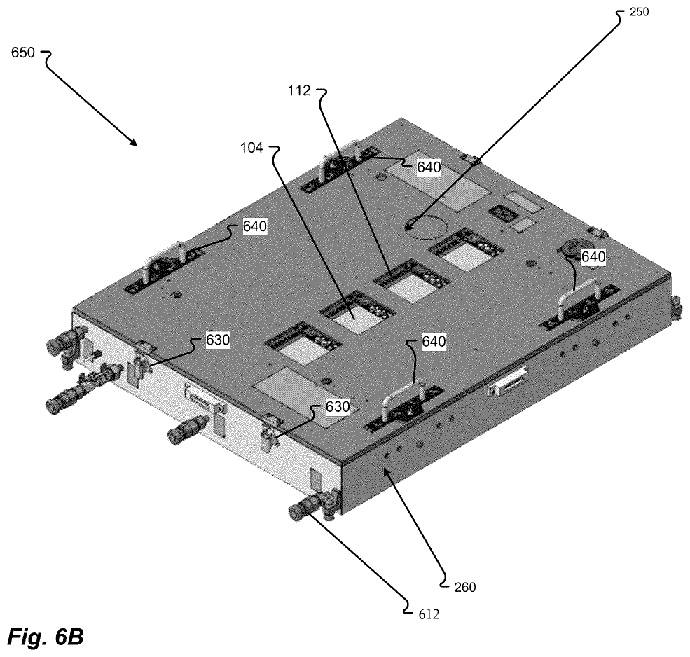

FIG. 6a is a diagram illustrating an isometric view of a liquid conductive cooling rework device 600 with the top fixture 250 separated from the tank 260 according to an embodiment of the present disclosure. As illustrated in FIG. 6a, the top fixture 250 includes the PCBA 112 and components 104 provided on the topside of the PCBA 112. The tank 260 includes the inner layer 420, the outer layer 430 and the inner tank 440. The inner tank 440 further includes the temperature sensor 410, a refill partition 604 and an overflow hole 608 that manages the level 455 of the coolant 450 in the inner tank 440 of the tank 260 during the rework process. The tank 260 further includes connectors 612 provided to connect the tank 260 to the circulating machine 550 by the tank inlet pipe 508 and a tank outlet pipe 504 and provided to connect the tank 260 to the overflow storage tank 530 and the exhaust storage tank 540 by the outlet pipe 512 and the inlet pipe 516.

FIG. 6b is a diagram illustrating an isometric view of a liquid conductive cooling rework device 650 with the top fixture 250 connected to the tank 260 according to an embodiment of the present disclosure. As illustrated in FIG. 6a, the top fixture 250 includes the PCBA 112 and components 104 provided on the topside of the PCBA 112. The tank 260 includes connectors 612 provided to connect the tank 260 to the circulating machine 550 by the tank inlet pipe 508 and a tank outlet pipe 504 and provided to connect the tank 260 to the overflow storage tank 530 and the exhaust storage tank 540 by the outlet pipe 512 and the inlet pipe 516. The top fixture 250 and the tank 260 may be releasably engageable with one another in any suitable manner. For example, closing mechanisms 630 are provided on both the top fixture 250 and the tank 260 is provided for releasably engaging the top fixture 250 with the tank 260. Closing mechanisms 630 may include, for example, a latch, a buckle, a clasp, a clamp, a clip, a locking device, a separable fastener, a pin, a mechanical interlock, a strap, a snap-fit connection, a threaded connection, etc. The top fixture 250 is provided onto the tank 260. According to one embodiment of the present disclosure, closing mechanisms 630 may be provided on one set of opposite sides of the top fixture 250 and the tank 260. According to a further embodiment of the present disclosure, the closing mechanism 630 may be provided on both sets of opposing sides of the top fixture 250 and the tank 260. According to an embodiment of the present disclosure, the latch or buckle is preferable since the latch or the buckle is used and provides effective retention for the and top fixture 250 the tank 260. The top fixture 250 further includes handles 640. The handles 640 are provided to transport the hot air liquid conductive cooling rework device 200.

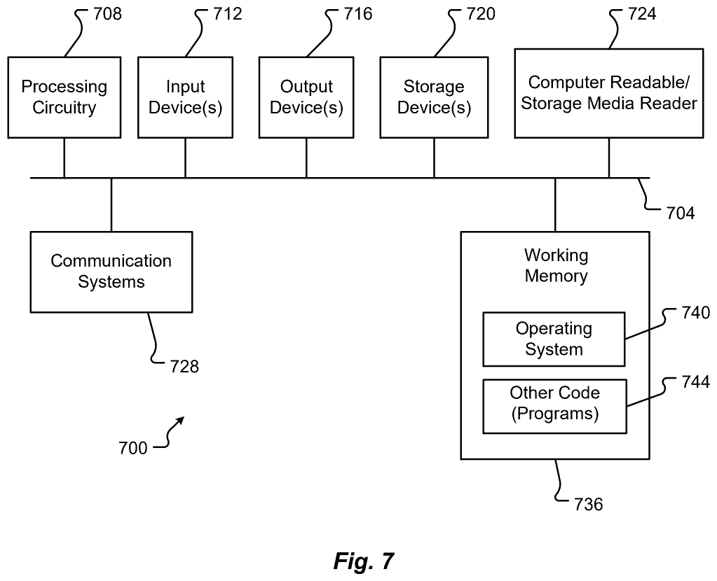

FIG. 7 is a block diagram illustrating a computing system 700 used with the hot air liquid conductive cooling rework system 500 according to an embodiment of the present disclosure. More specifically, this example illustrates one embodiment of a computing system 700 upon which the systems, controllers, and/or components described herein may be deployed or executed. The computing system 700 may have all of the components normally used in connection with a personal computing device. The computing system 700 is shown including hardware elements that may be electrically coupled via a bus 704. The hardware elements may include one or more processing circuitry 708 (e.g., a processor, a digital signal processor, etc.); one or more input devices 712 (e.g., a mouse, a keyboard, etc.); and one or more output devices 716 (e.g., a display device, a printer, another computing device, etc.). The computing system 700 may also include one or more storage devices 720. By way of example, storage device(s) 720 may be disk drives, optical storage devices, solid-state storage devices such as a Random-Access Memory (RAM) and/or a Read-Only Memory (ROM), which can be programmable, flash-updateable and/or the like.

The computing system 700 may additionally include a computer-readable storage media reader 724; a communications system 728 (e.g., a modem, a network card (wireless or wired), an infra-red communication device, etc.); and working memory 736, which may include RAM and ROM devices as described above.

The computer-readable storage media reader 724 can further be connected to a computer-readable storage medium, together (and, optionally, in combination with storage device(s) 720) comprehensively representing remote, local, fixed, and/or removable storage devices plus storage media for temporarily and/or more permanently containing computer-readable information. The communications system 728 may permit data to be exchanged with a network and/or any other computer described above with respect to the computer environments described herein. Moreover, as disclosed herein, the term “storage medium” may represent one or more devices for storing data, including ROM, RAM, magnetic RAM, core memory, magnetic disk storage mediums, optical storage mediums, flash memory devices and/or other machine-readable mediums for storing information.

Computing system 700 may also include software elements, shown as being currently located within a working memory 736, including an operating system 740 and/or other code 744. It should be appreciated that alternate embodiments of a computing system 700 may have numerous variations from that described above. For example, customized hardware might also be used and/or particular elements might be implemented in hardware, software (including portable software, such as applets), or both. Further, connection to other computing devices such as network input/output devices may be employed.

Examples of the processing circuitry 708 as described herein may include, but are not limited to, an FPGA, an ASIC, and/or a CPU, such as at least one of Qualcomm® Snapdragon® 800 and 801, Qualcomm® Snapdragon® 620 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22 nm Haswell, Intel® Core® i5-3570K 22 nm Ivy Bridge, the AMD® FX™ family of processors, AMD® FX-4300, FX-6300, and FX-8350 32 nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

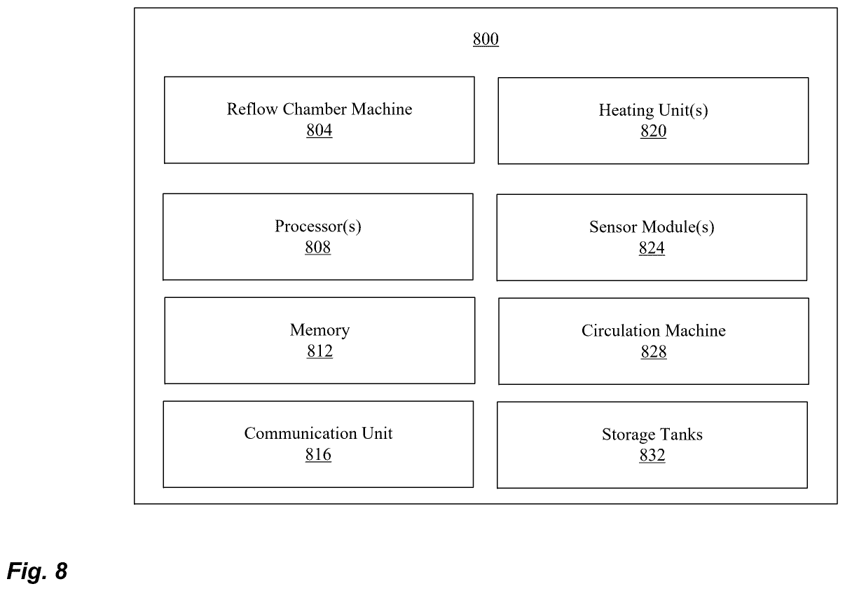

According to an embodiment of the present disclosure, the computing system 700 is used in conjunction with a reflow module to form a reflow environment. For example, the reflow module is connected as an input device 712 and/or an output device 716 of the computing system 700 to form the reflow environment. The reflow module is shown in greater detail in FIG. 8. As stated above, storage device 720 may store various types of information. For instance, storage device 720 may receive real-time information from the reflow module, including temperature data and other sensor information. As noted above, such information may be timestamped, or otherwise indexed, so that a solder status along a specific portion of the PCBA 112 can be determined at a particular point in the reflow process. The storage device 720 may also store models or other temperature profile information, for instance based on past reflow evaluations for the same or similar PCBA 112. In one scenario, the real-time temperature data and other sensor information capability of the present technology can be used to detect a phase transformation point in the solder. Afterwards, the reflow environment can then collect the relevant information and use the information to predict conditions for rework. Such information may be used as inputs that are fed back into the reflow environment to modify the reflow profile, such as the peak temperature, overall reflow time, time above liquidus (TAL), ramp up and ramp down rates, solder material or alloy type.

FIG. 8 is a block diagram of an example reflow module 800 for the hot air liquid conductive cooling rework system 500 according to an embodiment of the present disclosure. As illustrated in FIG. 8, the reflow module 800 includes a reflow chamber 804 including the liquid conductive cooling rework device 600, one or more heating units 820 (e.g., the nozzle 120) and one or more sensor modules 824 (e.g., temperature sensor 410). During operation, the liquid conductive cooling rework device 600 is placed within the reflow chamber machine 804 which may be set in a vacuum. The reflow module also includes one or more processors 808, memory 812 and a communication unit 816, for instance to communicate with computing system 700.

The reflow chamber machine 804 is configured to receive the liquid conductive cooling rework device 600. The heating unit(s) 820 (e.g., the nozzle and tank 260) are configured to heat the liquid conductive cooling rework device 600 to specific temperatures according to one or more temperature profiles stored in the memory 812, for instance under the control of the one or more processors 808. By way of example, the processor(s) 808 may receive the temperature profile(s) from the computing system 700 or a remote database via the communication unit 816. Each profile may be based on a specific PCBA 112 being fabricated, the types of components on the PCBA 112 including targeted and nontargeted components, and/or other factors such as soldering or circuit board manufacturing standards, for instance to produce PCBAs 112 that are able to operate for extended periods of time (e.g., months or longer) in the stratosphere.

The reflow process within the reflow chamber machine 804 may include control of the TAL to ensure that the solder flows as desired for the connections with different components. For instance, the ramp up rate may be no more than 1° C.-3 ° C./sec, and the TAL may be between 30 and 100 seconds. These factors may be impacted by the size of the PCBA 112, the characteristics of the selected components (e.g., duplexers v. flip-chips or BGAs), and other issues. Once the reflow process is finished and a determined temperature has been reached (e.g., room temperature, such as about 20° C.-22 ° C., or more or less), the PCBA 112 may be removed from the reflow chamber. At this point, the PCBA 112 may be routed through a series of inspections and measurements, such as automated optical inspection, X-ray inspection and quality control. If the PCBA 112 meets the requisite standards (e.g., IPC standards) at these inspection stages, then the circuitry of PCBA 112 is tested to confirm its functionality.

The sensor modules 824 may include, by way of example, one or more temperature sensors (e.g., temperature sensor 410 and gas sensors (such as when an inert gas is used during reflow). This can include fixed and/or adjustable thermocouples disposed along the reflow chamber machine 804. There may be multiple temperature sensors dispersed along the reflow chamber machine 804, a circulating machine 828 (e.g., circulating machine 550), and storage tanks 832 (e.g., overflow storage tank 530 and exhaust storage tank 540). Such sensors may be arranged at particular locations to ensure highly accurate temperature readings for the soldered areas of interest. The locations may be selected based on the types of components of interest. For instance, passive elements such as resistors do not need a thermocouple, while in contrast more complex packages such as BGAs, QFNs and through hole packages may benefit from thermocouples being placed as close as possible to the respective pads of those components.

In one embodiment of the present disclosure, the temperature sensors are able to make measurements continuously with a high level of granularity. By way of example, this can include making measurements every 0.01 s-0.05 s (or more or less), with an accuracy on the order of 0.1° C. (or more or less). This allows the rework system to measure peak temperature, TAL, ramp up and ramp down rates, etc., as the solder begins to transition from solid to liquid phase. The information from each sensor can be timestamped and associated with the specific sensor. Such information may be stored in a database or other record in the memory 812, and/or transmitted in real time to the computing system 700 or a remote database. Moreover, information for the circulation machine 828 and the storage tanks can be monitored. For example, the amount and the temperature of the conductive fluid provided in the circulating machine 828 can be monitored. Likewise, the amount and the temperature of the coolant provided in the storage tanks 832 can be monitored. More particularly, the level and temperature of the coolant provided in the inner tank 440 of the tank 260 can be monitored to determine that nontargeted components 204a-204c provided on the bottom side of the PCBA 112 are not damaged due to the excessive heat to rework a targeted component on the topside of the PCBA 112.

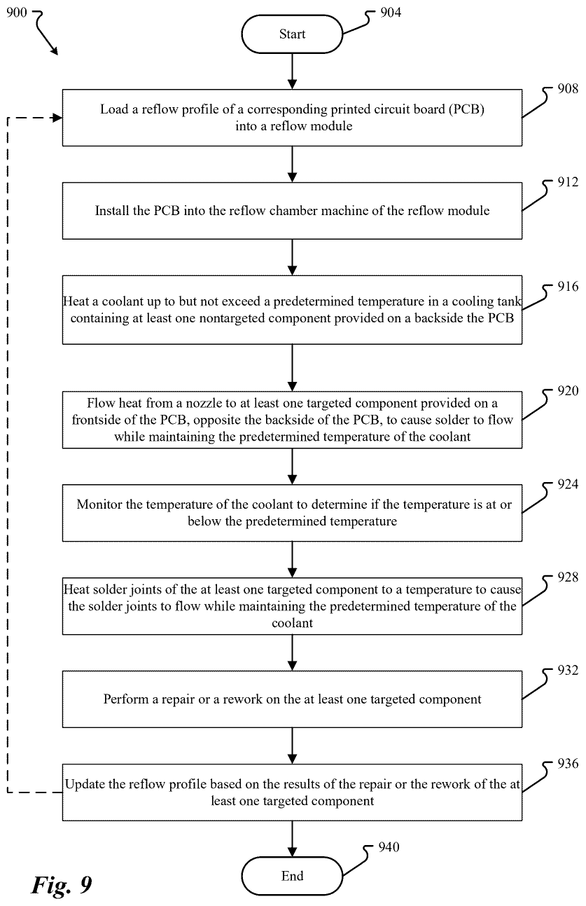

FIG. 9 is a flowchart illustrating an example method 900 for rework and assembly of components provided on a double-sided PCBA used with the hot air liquid conductive cooling rework system 500 according to an embodiment of the present disclosure. While a general order of the steps of method 900 is shown in FIG. 9, method 900 can include more or fewer steps or can arrange the order of the step differently than those shown in FIG. 9. Further, two or more steps may be combined in one step. Generally, the method 900 starts at a START operation at step 904 and ends with an END operation at step 940. Hereinafter, the method 900 shall be explained with reference to the systems, components, modules, applications, etc. described in conjunction with FIGS. 1-8.

Method 900 begins at START operation at step 904 and proceeds to step 908, where a reflow profile of a corresponding printed circuit board assembly (PCBA) 112 is loaded into a reflow module 800. As stated above in FIG. 8, the reflow module 800 represents the hot air liquid conductive cooling rework system 500. Loading the reflow profile into the reflow module 800 may include loading the reflow profile into memory 812 and/or accessing the reflow profile by the processor(s) 808. According to an alternative embodiment of the present disclosure, loading the reflow profile into the reflow module 800 may include loading the reflow profile from storage device(s) 720 of the computing system 700 or loading the reflow profile from a remote database via the communication unit 816.

After loading the reflow profile of a corresponding PCBA 112 into the reflow module 800 at step 908, method 900 proceeds to step 912, wherein the PCBA 112 is installed into the reflow chamber machine 804 of the reflow module 800. According to an embodiment of the present disclosure, the PCBA 112 is provided within the hot air liquid conductive cooling rework device 200 as illustrated in FIG. 2. As noted above, there may be multiple temperature sensors 824 disposed along the reflow chamber machine 804 near or otherwise adjacent to components of interest, for instance at two or three different corners of the reflow chamber machine 804. According to an embodiment of the present disclosure, temperature sensor 824 may include temperature sensor 410 used for measuring the temperature of the coolant 450.

After installing the PCBA 112 into the reflow chamber machine 804 at step 912, method 900 proceeds to step 916, where a coolant 450 is heated to a selected controller temperature in a tank 260 containing at least one nontargeted component 204 provided on a second side (e.g., bottom side) of the PCBA 112 according to the reflow profile. As discussed above, a double-sided PCBA is provided. The bottom side of the double-sided PCBA (e.g., the side that is not being reworked) is submerged into the tank with a dielectric solution provided therein. The dielectric solution is provided such that the components on the bottom side of the double-sided PCBA (e.g., nontargeted components) are submerged, but the bottom side of the double-sided PCBA is in intimate contact (e.g., slightly above or slightly in contact) with the dielectric solution. According to the embodiment of the present disclosure, the dielectric solution has an operating temperature in a range between 125° C. to 350° C. and more specifically in a range between 150° C. to 290° C. The dielectric solution ensures that the bottom side of the PCBA remains at a selected controlled temperature sufficient to prevent solder from flowing (e.g., making the solder liquidus). Thus, the heat conduction on the bottom side of the PCBA is managed by the thermally controlled dielectric solution and the nontargeted components are prevented from being damaged due to increased heat when a targeted component needs to be reworked.

According to an alternative embodiment of the present disclosure, a double-sided PCBA is provided where some of the components provided on the frontside of the PCBA are spaced close to each other (e.g., neighboring components). For example, some of the neighboring components provided on the topside of the PCBA are spaced within an inch or less from each other. To ensure that the nontargeted neighboring components are not affected by the hot air reflow process of a targeted component, the dielectric solution is applied to the neighboring nontargeted component(s) that are spaced one inch or less from the targeted component(s). For example, a wall, a barrier, a moat, a trench, a dike, etc., may be provided to surround the nontargeted component(s) such that the targeted component(s) are separated from the nontargeted neighboring component(s). The dielectric solution is provided within the wall, the barrier, the moat, the trench, the dike, etc. of the neighboring nontargeted component(s). The dielectric solution is at room temperature or cooler. For example, the temperature of the dielectric solution is in the range of 15° C. to 20° C. or cooler.

After heating the coolant 450 to the selected controlled temperature in the tank 260 containing at least one nontargeted component 204 provided on a second side of the PCBA 112 according to the reflow profile at step 916, method 900 proceeds to step 920, where heat from a nozzle 220 of the reflow chamber machine 804 is flown to at least one targeted component 104 provided on a first side (e.g., topside) of the PCBA 112, opposite to the bottom side of the PCBA 112, to cause solder to flow while maintaining the selected controlled temperature of the coolant 450. According to embodiments of the present disclosure, the selected controlled temperature of the coolant 450 is maintained by the tank 260 having a two-layer structure (an inner layer and an outer layer) surrounding an inner tank region. The inner layer is a circulatory layer, and the outer layer is an insulating layer. The inner tank region is provided with a dielectric solution (e.g., a coolant 450). The inner layer is provided with a thermally conductive media to maintain a steady state temperature of the components 240 by controlling the temperature of the dielectric solution. Moreover, heating units provided in the circulating machine 550 and the temperature sensor 410 are used to monitor and adjust the temperature of the coolant 450.

After flowing heat from the nozzle 220 of the reflow chamber 804 to at least one targeted component 104 on the topside of the PCBA 112, opposite the bottom side of the PCBA 112, to cause solder to flow while maintaining the selected controlled temperature of the coolant 450 at step 920, method 900 proceeds to step 924, where the temperature of the coolant 450 is monitored to ensure the temperature is at the selected controlled temperature. According to embodiments of the present disclosure, the circulating machine 550, the overflow storage tank 530 and the exhaust storage tank 540 along with sensors are used to ensure the temperature is at the selected controlled temperature.

After monitoring the temperature of the coolant 450 to ensure the temperature is at the selected controlled temperature at step 924, method 900 proceeds to step 928, where solder joints of the at least one targeted component 104 are heated to a temperature to cause the solder joints to flow while maintaining the selected controlled temperature of the coolant 450.

After heating the solder joints of the at least one targeted component 104 to a temperature to cause the solder joints to flow while maintaining the selected controlled temperature of the coolant 450 at step 928, method 900 proceeds to step 932, where a rework on the at least one targeted component 104 is performed.

After performing a rework on the at least one targeted component 104 at step 932, method 900 proceeds to step 936, where the reflow profile is updated based on the results of the rework of the at least one targeted component 104. According to an embodiment of the present disclosure, the updated reflow profile may be reloaded back to step 908 (as shown by the dashed arrow).

After updating the reflow profile based on the results of the rework of the at least one targeted component 104 at step 936 (and if the updated reflow profile is not reloaded back to step 908), method 900 ends with the END operation at step 940. Any of the steps, functions, and operations discussed herein can be performed continuously and automatically.

Various aspects of the apparatus, method and techniques described herein may be used alone, in combination, or in a variety of arrangements not specifically discussed in the embodiments of the present disclosure described in the foregoing description and is therefore not limited in its application to the details and arrangement of components set forth in the foregoing description or illustrated in the drawings. For example, aspects described in one embodiment of the present disclosure may be combined in any manner with aspects described in other embodiments of the present disclosure.

The foregoing embodiments of the present disclosure are only intended for describing the technical solutions of this disclosure other than limiting this disclosure. Although this disclosure is described in detail with reference to the foregoing embodiments, a person of ordinary skill in the art should understand that they may still make modifications to the technical solutions described in the foregoing embodiments or make equivalent replacements to some technical features thereof, without departing from the scope of the technical solutions of embodiments of this disclosure.

Furthermore, while the embodiments illustrated herein show the various components in a single device, certain components can be in one or multiple devices. Thus, it should be appreciated that the components can be combined into one or more devices.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire, and fiber optics, and may take the form of acoustic or light waves, such as those generated during radio-wave and infra-red data communications.

While the flowcharts have been discussed and illustrated in relation to a particular sequence of events, it should be appreciated that changes, additions, and omissions to this sequence can occur without materially affecting the operation of the disclosed embodiments, configuration, and aspects.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

A number of variations and modifications of the disclosure can be used. It would be possible to provide for some features of the disclosure without providing others.

The present disclosure, in various embodiments, configurations, and aspects, includes components, methods, processes, systems and/or apparatus substantially as depicted and described herein, including various embodiments, subcombinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

What is claimed is:

1. An apparatus for reworking or removing circuit components provided on both sides of a printed circuit board assembly (PCBA), comprising:
a tank containing a liquid medium at a predetermined temperature;
a top cover having a first side and a second side opposite to the first side,
wherein the second side of the top cover is in contact with a top surface of the tank;
a PCBA having a first side and a second side opposite the first side and attached to the top cover;
a plurality of circuit components,
wherein at least one of the plurality of circuit components is provided on the first side of the PCBA and at least another of the plurality of circuit components is provided on the second side of the PCBA, below the second side of the top cover and submerged in the liquid medium; and
a nozzle connectable with a heat source and providing heat from the heat source to the at least one of the plurality of circuit components provided on the first side of the PCBA for rework or removal.

2. The apparatus of claim 1, wherein the liquid medium is maintained at the predetermined temperature during providing heat to the at least one of the plurality of circuit components provided on the first side of the PCBA for rework or removal.

3. The apparatus of claim 1, wherein the heat to the at least one of the plurality of circuit components provided on the first side of the PCBA for rework or removal is at a temperature higher than a melting temperature of solder bonded to the at least one of the plurality of circuit components provided on the first side of the PCBA such that the solder is melted.

4. The apparatus of claim 1, wherein the liquid medium covers 0.75 millimeters (mm) or less of the second side of the PCBA.

5. The apparatus of claim 1, wherein the liquid medium includes at least one of Gaulden HT, a class of organofluorine compounds that include perfluoropolyether (PFPE) fluorinated fluid.

6. The apparatus of claim 1, wherein the tank includes a temperature sensor used to monitor the temperature of the liquid medium.

7. The apparatus of claim 1, wherein the tank includes a two-layer structure of an inner layer and an outer layer surrounding an inner tank region of the tank and wherein the liquid medium is provided within the inner tank region.

8. The apparatus of claim 7, wherein the inner layer is a circulatory layer that includes silicon, and the outer layer is an insulating layer that includes rock wool.

9. The apparatus of claim 1, wherein the predetermined temperature is in a range of 150° C. to 290° C.

10. The apparatus of claim 3, wherein the solder includes tin (Sn), lead (Pb), silver (Ag), copper (Cu), zinc (Zn), bismuth (Bi), antimony (Sb), gold (Au) and/or indium (In).

11. The apparatus of claim 1, wherein the top cover is interchangeable based on a number of the plurality of circuit components provided on the first side of the PCBA.

12. The apparatus of claim 3, wherein the melting temperature of the solder ranges from 118° C. to 280° C.

13. A method for reworking or removing circuit components provided on both sides of a printed circuit board assembly (PCBA), comprising:
providing a printed circuit board assembly (PCBA) with circuit components provided on a first side and a second side, opposite the first side of the PCBA;
immersing the circuit components provided on the second side of the PCBA into a tank containing a liquid medium at a predetermined temperature; and
providing a nozzle connectable with a heat source over at least one of the circuit components provided on the first side of the PCBA for rework or removal while maintaining the predetermined temperature of the liquid medium.

14. The method of claim 13, further comprising heating the at least one of the circuit components provided on the first side of the PCBA to a temperature higher than a melting temperature of solder bonded to the at least one of the circuit components provided on the first side of the PCBA such that the solder is melted.

15. The method of claim 13, wherein the liquid medium includes at least one of Gaulden HT, a class of organofluorine compounds that include perfluoropolyether (PFPE) fluorinated fluid.

16. The method of claim 13, further comprising:
providing the tank to include a two-layer structure of an inner layer and an outer layer surrounding an inner tank region of the tank; and
providing the liquid medium within the inner tank region.

17. The method of claim 16, further comprising:
providing the inner layer with silicon; and
providing the outer layer with rock wool.

18. The method of claim 14, further comprising providing the melting temperature of the solder in a range of 118° C. to 280° C.

19. The method of claim 13, further comprising interchanging the top cover based on a number of the circuit components provided on the first side of the PCBA.

20. A reflow method, comprising:
loading a reflow profile of a printed circuit board assembly (PCBA) into a reflow system;
installing the PCBA provided within a rework device into a reflow chamber machine of the reflow system,
wherein the reflow device includes:
a tank containing a liquid medium at a predetermined temperature;
a top cover having a first side and a second side opposite to the first side,
wherein the second side of the top cover is in contact with a top surface of the tank, and
wherein the PCBA has a first side and a second side opposite the first side and attached to the top cover; and
a plurality of circuit components,
wherein at least one of the plurality of circuit components is provided on the first side of the PCBA and at least another of the plurality of circuit components is provided on the second side of the PCBA, below the second side of the top cover and submerged in the liquid medium;
providing a nozzle connectable with a heat source over the at least one of the plurality of circuit components provided on the first side of the PCBA for rework or removal while maintaining the predetermined temperature of the liquid medium;
performing rework on the at least one of the plurality of circuit components provided on the first side of the PCBA; and
updating the reflow profile based on a result of the rework performed on the at least one of the plurality of circuit components provided on the first side of the PCBA.
